(19) United States
(12) Patent Application Publication
(10) Pub. No.: US 2025/0158350 A1
(43) Pub. Date: May 15, 2025

(54) SEMICONDUCTOR LASER WITH A RADIATION GUIDING ELEMENT

(71) Applicant: ams-OSRAM International GmbH, Regensburg (DE)

(72) Inventor: Markus KEIDLER, Pettendorf (DE)

(73) Assignee: ams-OSRAM International GmbH, Regensburg (DE)

(21) Appl. No.: 18/836,430

(22) PCT Filed: Nov. 24, 2022
(86) PCT No.: PCT/EP2022/083179

§ 371 Date: Aug. 7, 2024

(30) Foreign Application Priority Data
Feb. 9, 2022 (DE) 10 2022 201 340.9

(51) Int. Cl. H01S 5/02253

(52) U.S. Cl. CPC H01S 5/02253

(57) ABSTRACT

The invention relates to a semiconductor laser, wherein a radiation guiding element (3) is arranged on a laser diode (2), comprising including a material or consisting of a material that can be applied by means of the laser radiation (5) on the laser diode (2). In addition, a radiation transmission element (8), in particular a radiation outlet window (8a), for a semiconductor laser (1) is provided, wherein one or more optical elements (31) are arranged on a base element (80), comprising including a corresponding material. A laser housing (9) with a radiation outlet window (8a) of this type and a corresponding production method are also provided.

### CROSS-REFERENCE TO RELATED APPLICATIONS

The present application is a national stage entry from International Application No. PCT/EP2022/083179, filed on Nov. 24, 2022, published as International Publication No. WO 2023/151842 Al on Aug. 17, 2023, and claims priority to German Patent Application No. 10 2022 201 340.9, filed Feb. 9, 2022, the disclosures of all of which are hereby incorporated by reference in their entireties.

### FIELD

The invention relates to a semiconductor laser having a radiation guidance element, more particularly an optical element or light guide, and to a corresponding production method. The invention also relates to a radiation transmission element, more particularly radiation exit window for a laser housing, having at least one optical element, and to a corresponding production method.

### BACKGROUND

One object to be achieved is that of specifying a semiconductor laser which is efficiently encapsulated and can be produced efficiently. Another object is that of a specifying semiconductor laser having a self-adjusting radiation guidance element, more particularly an optical element or light guide. A further object is that of specifying a corresponding radiation transmission element, more particularly a radiation exit window for a laser housing. The objects are achieved by the devices and the production methods having the features of the independent claims. Preferred developments are subjects of the dependent claims.

### SUMMARY

According to one embodiment, the semiconductor laser comprises a laser diode which has an active zone for generating laser radiation and has a radiation exit region via which the laser radiation can exit the laser diode. The semiconductor laser also has a radiation guidance element which is arranged in the radiation exit region on the laser diode and is connected monolithically to the laser diode. The radiation guidance element comprises a substance or consists of a substance which can be applied by means of the laser radiation on the laser diode. More preferably, the radiation guidance element is arranged in the radiation exit region directly (without interlayer) on the laser diode or directly on a dielectric mirror.

Accordingly, the radiation guidance element can be applied in a self-aligning manner precisely on the beam exit region, by operating the laser diode for applying the radiation guidance element.

The radiation guidance element is preferably stable towards the laser radiation, also called “radiation-stable”, meaning that in an operating state it does not degrade, or not substantially, within a typical total operating time for the semiconductor laser.

The laser diode may in principle be any desired semiconductor laser diode.

Because of the particularly high power densities, the effect known as the optical tweezers effect is particularly pronounced for edge-emitting semiconductor laser diodes. In this case, as a result of the high power densities, organic and inorganic soiling/compounds are picked up from the ambient air and deposited on the laser facet. The high energy densities in the region of the laser facet allow decomposition and deposition/accumulation of particles and decomposition products to take place at the facet. In this case, there is an interaction with the emitted radiation, leading in turn to additional heating of the facet. As a result of the relationship described above, self-reinforcing effects may occur that may ultimately result in destruction of the laser (COD, catastrophic optical damage).

According to one embodiment, the radiation guidance element is designed as a protective element reducing such effects. The element may in particular be designed in such a way that it enables operation of the semiconductor laser in normal ambient air. For this it may have a certain minimum thickness. As a coupling element, however, it may also bridge the distance between laser and a radiation outcoupling element, as is explained more precisely later on.

Accordingly, the laser diode is preferably an edge-emitting laser diode. In this case, the radiation exit region is a region of the laser facet, meaning that the radiation guidance element is arranged in the radiation exit region on the laser facet, preferably directly on the laser facet, and is connected monolithically to the laser facet.

As mentioned, however, the diode may in principle be any desired semiconductor laser diode, more particularly a vertical cavity surface emitting laser (VCSEL) or else a photonic crystal surface emitting laser (PCSEL). In the case of a VCSEL, the radiation guidance element may be applied—preferably directly—on a distributed Bragg reflector, via which the laser radiation exits in operation, or—preferably directly—on a substrate via which the laser radiation exits in operation. In the case of a PCSEL, the radiation guidance element may be applied—preferably directly—on a photonic crystal of the PCSEL.

The substance may in particular be an inorganic substance. The substance may comprise or consist of silicon, aluminum, tantalum, titanium or hafnium.

The substance may, for example, be a dielectric, such as: silicon dioxide SiO₂, aluminum oxide Al₂O₃, tantalum oxide TaO, tantalum dioxide TaO₂, ditantalum pentaoxide Ta₂O₅, titanium dioxide TiO₂, hafnium dioxide HfO₂. Experimentally, particularly good results have been achieved with silicon dioxide SiO₂.

The radiation guidance element may be designed as a radiation outcoupling element. This means that the radiation guidance element has a radiation outcoupling face, not connected to a further optical element, via which the radiation can be delivered to an atmosphere.

The radiation outcoupling element may be designed for shaping the laser radiation (called “optical element” below), and in particular may be designed as a refractive lens.

The lens may be designed in such a way that the laser radiation is widened by the lens effect, to enable operation of the semiconductor laser in normal ambient air. Alternatively, the radiation outcoupling element may enable self-adjusting focusing of the laser beam, to realize optimization of the beam profile. Alternatively, in addition to the radiation guidance element, there may be a radiation outcoupling element present that is connected monolithically to the radiation guidance element. The radiation guidance element may then constitute a coupling element (more particularly a light guide) with which the laser radiation is guided from the laser diode to the radiation outcoupling element. In the case of this embodiment as well, the beam outcoupling element may be configured for shaping the laser radiation. The beam outcoupling element may be any desired lens, more particularly a refractive lens, or else a prism which changes a direction of propagation of the laser radiation.

In this case, the radiation outcoupling element may be situated after the radiation guidance element along a beam path of laser radiation which can be generated with the semiconductor laser. This means that laser radiation generated when a laser diode is active is transmitted first through the radiation guidance element and then through the radiation outcoupling element. The semiconductor laser may further comprise a support at or on which the semiconductor laser and optionally the radiation outcoupling element are arranged. In particular, the laser and optionally the radiation outcoupling element may be mounted thereon.

According to one embodiment, the semiconductor laser has multiple laser diodes. An individual laser diode may likewise have multiple emission points. For example, the semiconductor laser may comprise a VCSEL array or an edge emitter having multiple laser ridges (laser bars).

Where multiple laser diodes and/or laser diodes having multiple emission points are present, there are preferably also a plurality of the above-described radiation guidance elements present; the semiconductor laser preferably has exactly the same number of radiation guidance elements as emission points.

The laser diode may be configured to emit light in the visible spectral range, more particularly in the blue spectral range. The semiconductor laser described is used preferably in a head-up display of a motor vehicle or as a beam source in a laser projector.

In a method for producing the above-described semiconductor laser, in the step S₁ a laser diode which has an active zone for generating laser radiation and has a radiation exit region is provided, and then in step S₂ a radiation guidance element is applied to the laser diode in the radiation exit region. The step S₂ comprises the substep of exposing (S₂ₐ) the laser diode to an atmosphere with a precursor, for example a metal organyl, and optionally a nitrogen and/or oxygen donor which can be induced to react in a chemical reaction by the laser radiation. The step S₂ also comprises the substep of operating S_{2b} the laser diode, so that the chemical reaction is induced and the precursor is converted into a substance which forms the radiation guidance element monolithically in the radiation exit region on the laser diode. The optional addition of oxygen prevents the deposition of carbon on the facet.

The laser diode may, as discussed earlier on, be an edge-emitting laser diode. In that case the radiation exit region is a laser facet and the radiation guidance element is arranged on the laser facet, preferably directly. Moreover, the laser diode may be a VCSEL or else a PCSEL. The radiation guidance element is preferably radiation-stable and more preferably a protective element, and preferably enables operation of the semiconductor laser in normal ambient air.

The precursor may in particular be an inorganic precursor. Correspondingly, the substance may be an inorganic substance. The precursor may comprise or consist of silicon, aluminum, tantalum, hafnium or titanium. Correspondingly, the substance may comprise or consist of silicon, aluminum, tantalum, hafnium or titanium.

Experimentally, particularly good results have been achieved with SiO₂. Here, a volatile silicone (SiₓH_{y}C_{z}), e.g., silane (SiₓH₂ₓ), is used as precursor. It reacts with oxygen O₂ from the atmosphere to give silicon dioxide SiO₂

SiₓH_{y}C_{z}+O₂->SiO₂+H₂O (+stable Siₓ₋ₒH_{y-m}C_{z-n})

The Si here may be replaced by a further metal for which the oxide formed has a suitable refractive index.

As mentioned earlier on, the radiation guidance element may be designed as a radiation outcoupling element, in which case it may be suitable for shaping the laser radiation. Alternatively, as mentioned earlier on, additionally to the radiation guidance element, there may be a radiation outcoupling element which is connected monolithically to the radiation guidance element.

A corresponding production method additionally comprises the step S₁ₐ of providing the radiation outcoupling element and the step S_{1b} of arranging the radiation outcoupling element relative to the laser diode in such a way that in operation of the laser diode, the laser radiation is transmitted through the radiation outcoupling element. Accordingly, subsequently in step S₂ₐ, both the laser diode and the radiation outcoupling element are exposed to the atmosphere with the precursor, and in step S_{2b}, during operation of the laser diode, the radiation guidance element is formed in the radiation exit region on the laser diode such that it connects the laser diode monolithically to the radiation guidance element.

As mentioned earlier on, the semiconductor laser may further comprise a support at or on which the semiconductor laser and optionally the radiation outcoupling element are arranged. As mentioned earlier on, the semiconductor laser may have multiple laser diodes, and in that case there may be a plurality of the radiation guidance elements generated. The laser diode may be configured to emit light in the visible spectral range, more particularly in the blue spectral range. The semiconductor laser described is preferably used in a head-up display of a motor vehicle or as a beam source in a laser projector.

According to one embodiment, a radiation transmission element, more particularly a radiation exit window for a laser housing, comprises a base element, more particularly a radiation exit window base element, and one or more optical elements arranged on the base element and connected monolithically to the base element. The optical elements again comprise a substance which can be applied by means of laser radiation on the base element, or consist thereof.

The base element may in particular be a radiation exit window base element, and in that case may preferably be a planar or predominantly planar sheet which is transparent to laser radiation.

Similarly to the semiconductor laser with radiation guidance element, described earlier on, the optical element or elements may be generated in a self-aligning manner on the base element, by operating a laser diode for applying the one or more optical elements.

The optical element is designed for shaping the laser radiation. This element may be a refractive lens. The lens may be designed in such a way that the laser radiation is widened by the lens effect. The substance may be the substances mentioned earlier on, more particularly silicon dioxide.

According to one embodiment, an optoelectronic device comprises one or more semiconductor laser diodes which each have an active zone for generating laser radiation and have a hermetic laser housing in which the semiconductor laser diodes are arranged. The radiation exit window described above is part of the hermetic laser housing. The laser diodes are arranged relative to the radiation exit window in such a way that each laser diode is assigned one of the optical elements, through which the laser radiation of the respective laser diode can exit in an operating state.

The laser diodes may be laser diodes of one of the types mentioned earlier on, for example edge-emitting laser diodes or a VCSEL array, and application in a head-up display or as a beam source in a laser projector is preferred.

In a method for producing a corresponding radiation transmission element, more particularly radiation exit window, the radiation transmission element is provided first in the step S₂₁. Subsequently, the optical element or elements is or are applied to the radiation transmission element in the step S₂₂. In this case, the radiation transmission element is first exposed (step S₂₂ₐ) to an atmosphere with a precursor which can be induced to react in a chemical reaction by laser radiation. Laser radiation is then generated, so that the chemical reaction is induced by the laser radiation and the precursor is converted into a substance which forms the optical elements monolithically on the radiation transmission element (step S_{22b}).

In a method for producing the optoelectronic device, first at least one semiconductor laser diode is provided (step S₃₁), having an active zone for generating laser radiation. Also provided is a hermetic laser housing having a radiation exit window base element (step S₃₂). The laser diode is then arranged in the laser housing (step S₃₃) in such a way that in an operating state, the laser radiation of the laser diodes can exit via the radiation exit window base element. The application of the optical element or elements in step S₃₄ to the radiation exit window base element takes place by exposing the radiation exit window base element, in step S₃₄ₐ, to an atmosphere with a precursor which can be induced to react in a chemical reaction by the laser radiation, and then, in step S_{34b}, operating the laser diode, so that the chemical reaction is induced and the precursor is converted into a substance which forms the at least one optical element monolithically on the radiation exit window base element.

In the step S₃₄ₐ, an interior of the laser housing is preferably kept free from the precursor.

The at least one laser diode may in particular be a laser diode of one of the types described above. The substance may be a substance of the substances described above, more particularly silicon dioxide, in which case the precursor may be a volatile silicone.

### BRIEF DESCRIPTION OF THE DRAWINGS

The invention is elucidated more closely below in association with the appended figures, which schematically show:

FIG. 1: a semiconductor laser according to a first exemplary embodiment,

FIG. 2: a method for producing the semiconductor laser according to the first exemplary embodiment,

FIG. 3: a semiconductor laser according to a second exemplary embodiment,

FIG. 4: a semiconductor laser according to a third exemplary embodiment,

FIG. 5: a method for producing the semiconductor laser according to the second and third exemplary embodiments,

FIG. 6: a radiation exit window according to one exemplary embodiment,

FIG. 7: a method for producing the radiation exit window according to the exemplary embodiment of FIG. 6,

FIG. 8: a hermetic laser housing according to one exemplary embodiment,

FIG. 9: a method for producing the hermetic laser housing according to the exemplary embodiment of FIG. 8.

### DETAILED DESCRIPTION

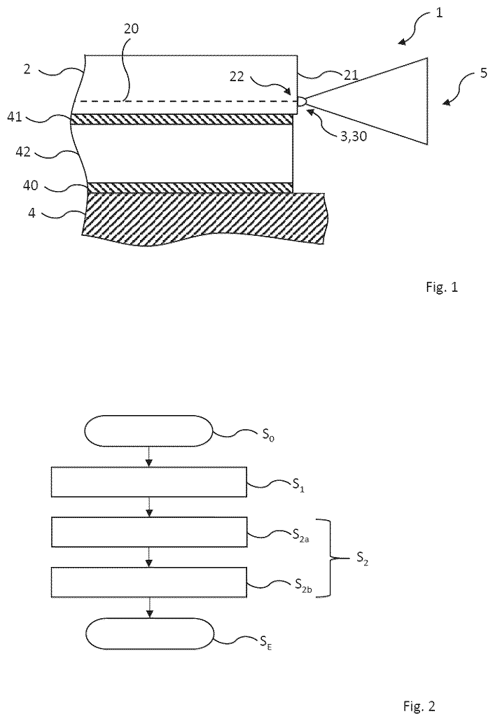

FIG. 1 shows a semiconductor laser 1 according to a first exemplary embodiment. The semiconductor laser 1 comprises a semiconductor laser diode 2, which is arranged on a support 4. Located between the support 4 and the semiconductor laser diode 2 in the present exemplary embodiment is a submount (assembly element) 42, which is connected by means of a solder 40 and 41 (presently a solder layer) to the laser diode 2 and the support 4. The laser diode 2 possesses an active zone 20, which on application of a suitable voltage generates the laser radiation 5. The laser radiation 5 exits the laser diode 2 via the radiation exit region 22. Presently, the laser diode 2 is an edge-emitting laser diode. Accordingly, the radiation exit region 22 is a region of the laser facet 21. Arranged on the laser facet 21 in the radiation exit region 22 is a radiation guidance element 3. Alternatively, the laser diode 2 might also be a VCSEL or a PCSEL.

The radiation guidance element 3 comprises a substance or consists of a substance which can be applied by means of the laser radiation 5 on the laser diode 2. The radiation guidance element 3 enables operation of the semiconductor laser 1 in normal ambient air, and is therefore a protective element.

Presently, moreover, the radiation guidance element 3 is shaped as a refractive lens. The radiation guidance element 3 is therefore a radiation outcoupling element 30 which has a radiation outcoupling face via which the laser radiation 5 can be delivered to an atmosphere.

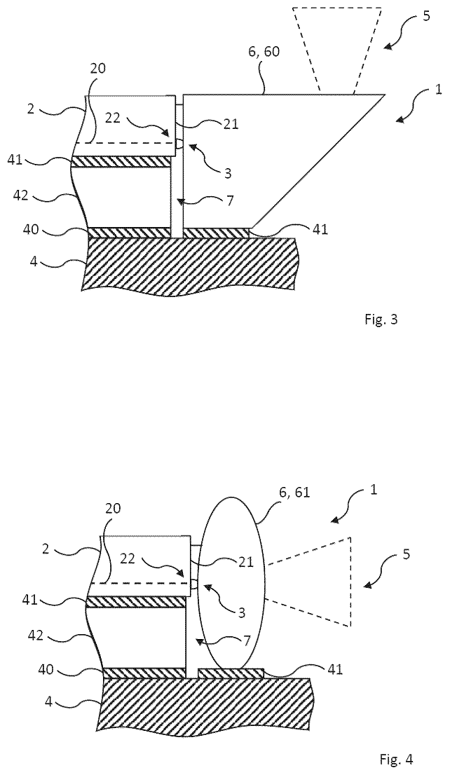

As mentioned above, the radiation guidance element 3 comprises a substance which can be applied by means of the laser radiation 5 on the laser diode 2. A corresponding method is described in more detail below in association with FIG. 2.

The method begins with the step S₀ Start. In the step S₁ the laser diode 2 is provided. Subsequently in the step S₂ the radiation guidance element 3 is applied on the laser diode 2. The step S₂ encompasses the component steps S₂ₐ and S_{2b}. In the step S₂ₐ the laser diode 2 is exposed to an atmosphere with a precursor which can be induced to react in a chemical reaction by laser radiation 5. In the step S_{2b} the laser diode is operated, so that the chemical reaction is induced and the precursor is converted into a substance which forms the radiation guidance element 3 in the radiation exit region 22 monolithically on the laser diode 2. The precursor may in particular be a silicone hydride or volatile silicone and the substance may be silicon dioxide. The method ends with the step S_{E} End. Any hydrocarbons present are oxidized to CO₂ by means of reaction with oxygen and are no longer available as reactants in the process.

FIG. 3 shows a semiconductor laser 1 according to a second exemplary embodiment. It is constructed substantially similarly to the first exemplary embodiment according to FIG. 1. However, in the semiconductor laser 1 according to the second exemplary embodiment, the radiation guidance element 3 is not a radiation outcoupling element 30. This means that electromagnetic radiation is not delivered into an atmosphere directly via the radiation guidance element 3. Instead, the radiation guidance element 3 is connected to a radiation exit element 6. As a light guide, it transmits the laser radiation 5, generated in the laser diode 2, to the radiation exit element 6. The radiation exit element 6 is presently a prism 60 which deflects the laser radiation 5 (in the present example at right angles, i.e., by around 90°). Like the semiconductor laser diode 2, this prism is arranged on the support 4 with a solder 41.

The laser radiation 5 exits, deflected by 90°, at the top side of the prism 60. An arrangement of this kind may be used in particular as what is called a toplooker laser housing, i.e., as a semiconductor laser housing where the laser radiation 5 exits at the top side perpendicular to a basal face of the housing. With the basal face, the housing can be arranged on a support, such as a printed circuit board, for example, and contacted. The semiconductor laser 1 is arranged in this case on an assembly which extends parallel to the basal face, and emits the laser radiation 5 parallel to the basal face (perpendicular to the surface normal of the basal face).

With the present exemplary embodiment, moreover, the interspace between the prism 60 and the semiconductor laser diode 2 or the submount 42 is filled with a filling material 7, to provide said interspace with protection from contaminants, with sealing, and with mechanical stabilization.

FIG. 4 represents a semiconductor laser 1 according to a third exemplary embodiment. It is constructed similarly to that of the second exemplary embodiment; in particular, the radiation guidance element 3 is connected monolithically to the semiconductor laser diode 2 and the radiation outcoupling element 6, and serves as a light guide between these elements. However, rather than being a prism 60, the radiation outcoupling element 6 is a lens 61 (presently a refractive lens).

Common to all of the exemplary embodiments described above is that the laser radiation 5, when coupled out into an atmosphere via one of the radiation outcoupling elements 30, 6, is widened in such a way that operation of the optoelectronic device in normal ambient air (e.g., terrestrial atmosphere at 300 kelvins) is possible.

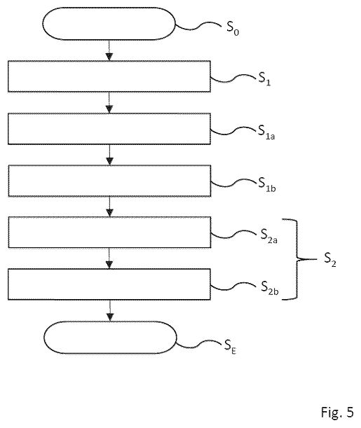

A method for producing the semiconductor laser 1 according to the second and third exemplary embodiments is represented in FIG. 5. The method begins with the step S₀ Start. First, in the step S₁, the semiconductor laser diode 2 is provided. Then, in the step S₁ₐ, the radiation outcoupling element 6 is arranged relative to the laser diode 2 in such a way that in the operation of the laser diode 2, the laser radiation 5 is transmitted through the radiation exit element 6. Presently, both the laser diode 2 and the radiation exit element 6 are arranged on a support 4 by means of solder 40, 41 and optionally a submount 42.

Subsequently, in the step S₂, the radiation guidance element 3 is applied to the laser diode 2 in such a way that it monolithically connects the laser diode 2 to the radiation outcoupling element 6. The step S₂ encompasses the component steps S₂ₐ and S2b. In the step S₂ₐ both the laser diode 2 and the radiation exit element 6 are exposed to the atmosphere with the precursor. The spacing between the radiation exit element 6 and the laser diode 2 was chosen in step S_{1b} to be so low that in the step S_{2b} of operation of the laser diode 2, the radiation guidance element 3 is formed in the radiation exit region 22 on the laser diode 2 and connects the laser diode 2 monolithically to the radiation guidance element 3. The method ends with the step S_{E} End.

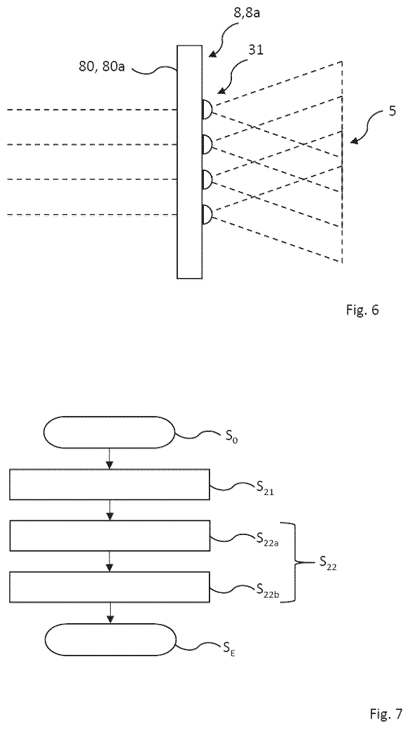

FIG. 6 shows a radiation transmission element 8, configured as a radiation exit window 8a, according to one exemplary embodiment. The radiation exit window 8a comprises a base element 80, configured as a radiation exit window base element 80a. The radiation exit window base element 80a may be a flat or sheetlike element which is transparent to laser radiation 5—for example, a glass pane. Arranged on the radiation exit window base element 80a are a plurality of optical elements 31 connected monolithically to the radiation exit window base element 80a. These elements are refractive lenses. They consist of a substance which can be applied by means of laser radiation 5 on the radiation exit window base element 80a.

As a result, the radiation exit window 8a of FIG. 6 can be generated particularly simply by means of the production method represented in FIG. 7. The first step, S₂₁, here is to provide the radiation exit window base element 80a. Thereafter, in the step S₂₂, the optical elements are applied to it. This application takes place by exposing the radiation exit window base element 80a in the step S₂₂ₐ to an atmosphere with a precursor 5 which can be induced to react in a chemical reaction by the laser radiation, and then generating laser radiation 5 in the step S_{22b}, so that the precursor is converted into a substance which forms the optical elements 31 on the radiation exit window base element 80a. The method ends with the step SE End.

In this case, preferably only one side of the radiation exit window base element 80a is exposed to the precursor, so that the optical elements 31 are formed only on one side of the radiation exit window base element 80a. The element, for example, may be charged with a protective gas.

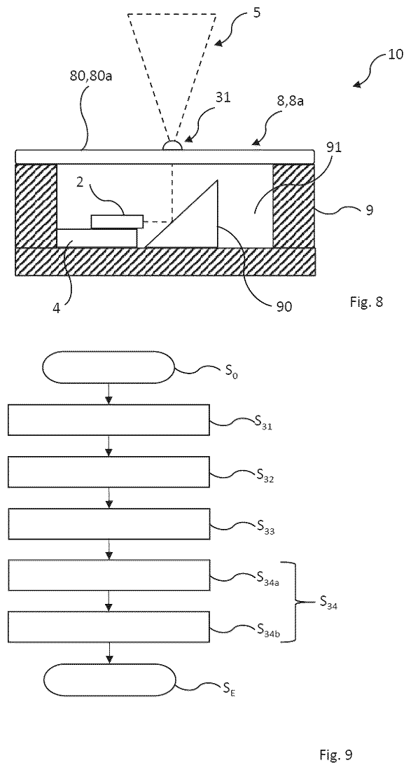

FIG. 8 represents an optoelectronic device 10 having a hermetic laser housing 9 with the above-described radiation exit window 8a. In the hermetic laser housing 9, semiconductor laser diodes 2 are arranged on a support 4. There is also a prism 90 located in the laser housing. As a result, the electromagnetic radiation 5 emitted by the semiconductor laser diode 2 is deflected by 90 degrees and delivered through the radiation exit window 8a. The laser diodes 2 are arranged relative to the radiation exit window 8a in such a way that each of the laser diodes 2 is assigned one of the optical elements 31 in such a way that the laser radiation emitted by the laser diode 2 in an operating state exits through the assigned optical element 31.

According to an alternative exemplary embodiment, in the case of the radiation exit window 8a according to FIG. 6 and the optoelectronic device 10 according to FIG. 8, there may also be only one optical element 31 and only one semiconductor laser diode 2. Likewise, the laser radiation 5 of the corresponding semiconductor laser diode 2 may also be split by means of a beam splitter into multiple laser beams and/or the laser diode may have multiple emission points. In that case, a laser diode 2 may be assigned two or more of the optical elements 31 through which the laser radiation 5 exits.

To produce the optoelectronic device 10, in principle, a corresponding radiation exit window 8a may be provided with the optical elements 31 and placed onto the laser housing 9, which already accommodates the laser diode 2 and the submount 4 and the prism 90, and aligned in such a way that the laser radiation 5 exits through the optical elements 31.

Preferably, however, the optoelectronic device 10 is produced according to the method represented in FIG. 9. The method begins with the step S₀ Start. Then, in the step S₃₁, the laser diodes are provided. Then, in the step S₃₂, the hermetic laser housing 9 is provided with the radiation exit window base element 80a. In the subsequent step S₃₃ the laser diodes are arranged in the laser housing 9 in such a way that in an operating state, the laser radiation 5 of the laser diodes 2 is able to exit via the radiation exit window base element.

In the subsequent method step S₃₄, the optical elements 31 are applied on the radiation exit window base element 80a. The step S₃₄ encompasses the component steps S₃₄ₐ and S_{34b}. In the component step S₃₄ₐ, the radiation exit window base element 80a is exposed to an atmosphere with a precursor which can be induced to react in a chemical reaction by the laser radiation 5, and in the component step S_{34b}, lastly, the laser diodes 2 are operated, so that the chemical reaction is induced and the precursor is converted into a substance which forms the optical elements 31 monolithically on the radiation exit window base element 80a. The method ends with the step S_{E} End.

The method has been described in association with multiple laser diodes 2, but it is also possible to use a single laser diode 2, in which case-depending on the number of emission points—possibly only one optical element 31 is generated.

The methods described may be used in principle to generate all radiation guidance elements 3, more particularly optical elements 31, which can be realized by means of the beam shaping of the initiating laser radiation 5.

The interior 91 of the hermetic laser housing 9 is preferably kept free from the precursor, so that no optical elements are formed there.

With all of the methods described, the radiation exit window base element 80a or the laser diode 2 may be exposed to the precursor by means of a reaction chamber. In all exemplary embodiments, the precursor may in particular be one of the precursors described earlier on, and the substance may be one of the substances described earlier on.

1. A semiconductor laser, comprising:
a semiconductor laser diode which has an active zone for generating laser radiation and has a radiation exit region via which the laser radiation can exit the laser diode, and
a radiation guidance element which is disposed in the radiation exit region on the laser diode and is connected monolithically to the laser diode, wherein the radiation guidance element comprises a substance which is applied by the laser radiation on the laser diode, further comprising a radiation outcoupling element, wherein the radiation outcoupling element is connected monolithically to the radiation guidance element.

2. A semiconductor laser as claimed in claim 1, wherein the laser diode is an edge-emitting laser diode and the radiation exit region is a region of the laser facet, wherein the radiation guidance element in the radiation exit region is arranged directly on the laser facet and is connected monolithically to the laser facet.

3. The semiconductor laser as claimed in claim 1, wherein the radiation guidance element is designed such that it enables operation of the semiconductor laser in normal ambient air.

4. The semiconductor laser as claimed in claim 1, wherein the radiation outcoupling element is situated after the radiation guidance element along a beam path of laser radiation which can be generated with the semiconductor laser.

5. The semiconductor laser as claimed in claim 1, wherein the substance comprises silicon, aluminum, tantalum, hafnium or titanium.

6. A method for producing a semiconductor laser, comprising:
providing a semiconductor laser diode which has an active zone for generating laser radiation and has a radiation exit region via which the laser radiation can exit the laser diode,
providing a radiation outcoupling element,
arranging the radiation outcoupling element relative to the laser diode in such a way that in the operation of the laser diode, the laser radiation is transmitted through the radiation outcoupling element,
applying a radiation guidance element to the laser diode in the radiation exit region, wherein the step of applying comprises:
exposing both the laser diode and the radiation outcoupling element to an atmosphere with a precursor which can be induced to react in a chemical reaction by the laser radiation,
operating the laser diode, so that the chemical reaction is induced and the precursor is converted into a substance which forms the radiation guidance element monolithically in the radiation exit region in such a way that it connects the laser diode monolithically to the radiation outcoupling element.

7. The method as claimed in claim 6, wherein the precursor and the substance comprise silicon, aluminum, tantalum, hafnium or titanium.

8. The method as claimed in claim 6, wherein a semiconductor laser is produced, the semiconductor laser comprising a semiconductor laser diode which has an active zone for generating laser radiation and has a radiation exit region via which the laser radiation can exit the laser diode, and a radiation guidance element which is disposed in the radiation exit region on the laser diode and is connected monolithically to the laser diode, wherein the radiation guidance element comprises a substance or consists of a substance which can be applied by means of the laser radiation on the laser diode, further comprising a radiation outcoupling element, wherein the radiation outcoupling element is connected monolithically to the radiation guidance element.

9. An optoelectronic device comprising:
one or more semiconductor laser diodes each having an active zone for generating laser radiation,
a hermetic laser housing in which the semiconductor laser diodes are arranged, with a radiation exit window,
the radiation exit window comprising:
a radiation exit window base element, and
one or more optical elements arranged on the radiation exit window base element and connected monolithically to the radiation exit window base element, wherein the optical elements comprise a substance which is applied by laser radiation on the radiation exit window base element,
wherein the laser diodes are arranged relative to the radiation transmission element in such a way that each laser diode is assigned one or more of the optical elements, through which the laser radiation of the respective laser diode can exit in an operating state.

10. The optoelectronic device as claimed in claim 9, wherein the substance comprises silicon, aluminum, tantalum, hafnium or titanium.

11. A method for producing an optoelectronic device, comprising:
providing one or more semiconductor laser diodes which have an active zone for generating laser radiation,
providing a hermetic laser housing having a radiation exit window base element,
arranging the laser diodes in the laser housing in such a way that in an operating state, the laser radiation of the laser diodes can exit via the radiation exit window base element,
applying one or more optical elements to the radiation exit window base element, wherein the step of applying comprises:
exposing the radiation exit window base element to an atmosphere with a precursor which can be induced to react in a chemical reaction by the laser radiation, and
operating the laser diodes, so that the chemical reaction is induced and the precursor is converted into a substance which forms the optical elements monolithically on the radiation exit window base element.

12. The method as claimed in claim 11, wherein the precursor and the substance comprise silicon, aluminum, tantalum, hafnium or titanium.
